(19) United States
(12) Patent Application Publication
(10) Pub. No.: US 2025/0043102 A1
(43) Pub. Date: Feb. 6, 2025

(54) LIQUID COMPOSITION, PREPREG, METAL SUBSTRATE WITH RESIN, WIRING BOARD, AND SILICA PARTICLES

(71) Applicants: AGC INC., Tokyo (JP); AGC SI-TECH CO., LTD., Kitakyushu-shi (JP)

(72) Inventor: Hiromichi KAMO, Chiyoda-ku (JP)

(73) Assignees: AGC INC., Tokyo (JP); AGC SI-TECH CO., LTD., Kitakyushu-shi (JP)

(21) Appl. No.: 18/923,800

(22) Filed: Oct. 23, 2024

Related U.S. Application Data
(63) Continuation of application No. PCT/JP2023/016013, filed on Apr. 21, 2023.

(30) Foreign Application Priority Data
Apr. 28, 2022 (JP) 2022-075146
Apr. 28, 2022 (JP) 2022-075461
Apr. 28, 2022 (JP) 2022-075462

(51) Int. Cl. C08K 3/36; C08J 5/24; H05K 1/03

(52) U.S. Cl. CPC C08K 3/36; C08J 5/249; H05K 1/0373; C08J 2371/12; C08K 2201/003; C08K 2201/006

(57) ABSTRACT

Provided are: a liquid composition containing a thermosetting resin and silica particles, the silica particles (1) having a specific water vapor adsorption amount and a specific moisture retention variation, (2) having a specific charge amount and a specific d50, and (3) having a specific powder friction angle, a specific d50, and a specific aggregation state; a prepreg, a metal substrate with a resin, and a wiring board using the liquid composition; and silica particles used in the liquid composition.

### CROSS-REFERENCE TO RELATED APPLICATION

This application is a Continuation of International Application No. PCT/JP2023/016013, filed on Apr. 21, 2023, which claims priority to Japanese Patent Application No. 2022-075461, filed on Apr. 28, 2022, Japanese Patent Application No. 2022-075462, filed on Apr. 28, 2022, and Japanese Patent Application No. 2022-075146, filed on Apr. 28, 2022. Each of the above applications is hereby expressly incorporated by reference, in its entirety, into the present application.

### TECHNICAL FIELD

The present disclosure relates to a liquid composition, a prepreg, a metal substrate with a resin, a wiring board, and silica particles.

### BACKGROUND ART

Liquid compositions containing thermosetting resin and silica particles are used to manufacture electrically insulating layers provided in metal-clad laminates that can be processed into printed wiring boards (see Patent Literature 1 and 2). Specifically, metal-clad laminates in which a semi-cured product of the liquid composition is layered on the surface of a metal substrate layer as an electrically insulating layer, and metal-clad laminates in which a glass cloth or the like impregnated with the liquid composition is layered on the surface of a metal substrate layer as an electrically insulating layer, are used. In recent years, there has been a demand for electrically insulating layers of printed wiring boards to have improved properties such as a low dielectric constant, a low dielectric tangent, and a low linear expansion coefficient, and toughness.

### CITATION LIST

### Patent Literature

Patent Literature 1: JP 2013-212956 A
Patent Literature 2: JP 2015-036357 A

### SUMMARY OF INVENTION

### Technical Problem

Meanwhile, from the viewpoint of reliability of wiring boards and the like, there is a demand for liquid compositions used for forming electrically insulating layers, such as a semi-cured product of the liquid composition and a glass cloth impregnated with the liquid composition, to have excellent adhesion to a metal substrate layer when cured. In particular, in association with the recent developments of finer wiring boards and less rough metal substrate layers, there is a demand for liquid compositions, cured products thereof, and prepregs to have more favorable adhesion of a cured product to a metal substrate layer. However, there is room for improvement in conventionally known liquid compositions, cured products thereof, and prepregs, in terms of the foregoing adhesion.

An object of one embodiment of the present disclosure is to provide a liquid composition and a prepreg capable of forming a cured product having excellent adhesion to a metal substrate layer. An object of one embodiment of the present disclosure is to provide a metal substrate with a resin and a wiring board having excellent adhesion between a cured product of a liquid composition and a metal substrate layer. An object of one embodiment of the present disclosure is to provide silica particles that can be used for forming a prepreg having excellent adhesion to a metal substrate layer when mixed with a liquid composition containing a thermosetting resin and cured.

Furthermore, in recent years, there is a demand for various properties in electrically insulating layers of printed wiring boards, which include having excellent toughness.

An object of one embodiment of the present disclosure is to provide a liquid composition and a prepreg capable of forming a cured product having excellent toughness. An object of one embodiment of the present disclosure is to provide a metal substrate with a resin and a wiring board that include a liquid composition capable of forming a cured product having excellent toughness, or a semi-cured product, a prepreg, or a cured product thereof. An object of one embodiment of the present disclosure is to provide silica particles that can be used for forming a prepreg capable of forming a cured product having excellent toughness, by being mixed with a liquid composition containing a thermosetting resin.

Furthermore, when mixing and dispersing silica particles in a curable resin, dispersibility of the silica particles as well as excellent mixing operability is desired. For example, when silica particles are mixed in a curable resin, there may be problems such as attachment of the silica particles to the wall of the container of a mixer (hereinafter also referred to as “wall attachment”) and foaming of the composition. However, there has been no knowledge regarding a method for obtaining a liquid composition that can efficiently suppress the wall attachment of the silica particles and foaming of the composition and that has excellent dispersibility of the silica particles.

An object of one embodiment of the present disclosure is to provide a liquid composition in which wall attachment of silica particles and foaming of the composition during mixing are suppressed and which has excellent dispersibility of the silica particles, a prepreg, a metal substrate with a resin, and a wiring board that use the liquid composition, and silica particles for use in the liquid composition.

### Solution to Problem

The solution to the above-described problem includes the following aspects.
(1) A liquid composition, comprising:
   a thermosetting resin; and
   silica particles having:
      a water vapor adsorption amount of from 0.01 to 10.00 cm³/g at a relative water vapor pressure of 0.8 on a water vapor adsorption isotherm at 25° C.; and
      a moisture retention variation of 20% or less, the moisture retention variation being calculated by (A-B)/A x 100, wherein A is a mass-based water content after being left to stand for 24 hours in an environment having a temperature of 85° C. and a relative humidity of 85%, and B is a mass-based water content after being left to stand for 24 hours in an environment having a temperature of 85° C. and a relative humidity of 85% and further being left to stand for 24 hours in an environment having a temperature of 25° C. and a relative humidity of 50%.
(2) The liquid composition according to (1), wherein the silica particles have a specific surface area of from 0.1 to 10.0 m²/g.
(3) The liquid composition according to (1) or (2), wherein the silica particles contain from 30 to 1500 ppm by mass of a metal element.
(4) The liquid composition according to any one of (1) to (3), wherein the silica particles have a median diameter d50 of from 1.0 to 10.0 μm.
(5) The liquid composition according to any one of (1) to (4), wherein an amount of the silica particles with respect to 100 parts by mass of the thermosetting resin is from 50 to 400 parts by mass.
(6) A liquid composition, comprising:
   a thermosetting resin; and
   silica particles having an absolute charge amount of from 0.7 to 200 nC/g and a median diameter d50 of from 1.0 to 10.0 μm.
(7) The liquid composition according to (6), wherein the silica particles are non-surface-treated particles.
(8) The liquid composition according to (6) or (7), wherein the silica particles have an internal carbon content of 10 mass % or less.
(9) The liquid composition according to any one of (6) to (8), wherein the silica particles have a median diameter d50 of from more than 1.0 μm to 5.0 μm.
(10) The liquid composition according to any one of (6) to (9), wherein an amount of the silica particles with respect to 100 parts by mass of the thermosetting resin is from 50 to 400 parts by mass.
(11) A liquid composition, comprising:
   a thermosetting resin; and
   silica particles having a powder kinetic friction angle of from 10 to 40 degrees and a median diameter d50 of from 1.0 to 10.0 μm, wherein a ratio of Al to B1 (A1/B1) is from 1.0 to 50.0, wherein Al is a median diameter d50 when the silica particles are dispersed in toluene, and B1 is a median diameter d50 when the silica particles are dispersed in toluene and further subjected to ultrasonic treatment.
(12) The liquid composition according to (11), wherein the silica particles have a repose angle of from 25 to 50 degrees.
(13) The liquid composition according to (11) or (12), wherein an amount of the silica particles with respect to 100 parts by mass of the thermosetting resin is from 10 to 400 parts by mass.
(14) The liquid composition according to any one of (1) to (13), wherein the thermosetting resin is an epoxy resin, a polyphenylene ether resin, or an ortho-divinylbenzene resin.
(15) The liquid composition according to any one of (1) to (14), further comprising at least one solvent selected from the group consisting of toluene, cyclohexanone, methyl ethyl ketone, and N-methylpyrrolidone.
(16) A prepreg, comprising:
   the liquid composition according to any one of (1) to (15) or a semi-cured product thereof; and
   a fibrous substrate.
(17) The prepreg according to (16), wherein the fibrous substrate comprises a glass component.
(18) A metal substrate with a resin, comprising:
   the liquid composition according to any one of (1) to (15) or a semi-cured product thereof, or a prepreg according to (16) or (17); and
   a metal substrate layer.
(19) The metal substrate with a resin according to (18), wherein the metal substrate layer is a copper foil.
(20) The metal substrate with a resin according to (19), wherein a maximum height roughness Rz of a surface of the copper foil facing the liquid composition, the semi-cured product, or the prepreg, is 2 μm or less.
(21) A wiring board, comprising:
   a cured product of the liquid composition according to any one of (1) to (15); and
   a metal wiring.
(22) Silica particles for use in forming a prepreg by being mixed with a liquid composition containing a thermosetting resin, wherein the silica particles have:
   a water vapor adsorption amount of from 0.01 to 10.00 cm³/g at a relative water vapor pressure of 0.8 on a water vapor adsorption isotherm at 25° C.; and
   a moisture retention variation of 20% or less, the moisture retention variation being calculated by (A−B)/A×100, wherein A is a mass-based water content after being left to stand for 24 hours in an environment having a temperature of 85° C. and a relative humidity of 85%, and B is a mass-based water content after being left to stand for 24 hours in an environment having a temperature of 85° C. and a relative humidity of 85% and further being left to stand for 24 hours in an environment having a temperature of 25° C. and a relative humidity of 50%.
(23) The silica particles according to (22), having a specific surface area of from 0.1 to 10.0 m²/g.
(24) Silica particles for use in forming a prepreg by being mixed with a liquid composition containing a thermosetting resin, wherein the silica particles have an absolute charge amount of from 0.7 to 200 nC/g and a median diameter d50 of from 1.0 to 10.0 μm.
(25) The silica particles according to (24), having an internal carbon content of 10% by mass or less.
(26) Silica particles for use in forming a prepreg by being mixed with a liquid composition containing a thermosetting resin,
   wherein the silica particles have a powder kinetic friction angle of from 10 to 40 degrees and a median diameter d50 of from 1.0 to 10.0 μm, and
   wherein a ratio of A1 to B1 (A1/B1) is from 1.0 to 50.0, wherein Al is a median diameter d50 when the silica particles are dispersed in toluene, and B1 is a median diameter d50 when the silica particles are dispersed in toluene and further subjected to ultrasonic treatment.
(27) The silica particles according to (26), having a repose angle of from 25 to 50 degrees.

### Advantageous Effects of Invention

According to one embodiment of the present disclosure, a liquid composition and a prepreg capable of forming a cured product having excellent adhesion to a metal substrate layer are provided. According to one embodiment of the present disclosure, a metal substrate with a resin and a wiring board having excellent adhesion between a cured product of a liquid composition and a metal substrate layer are provided. According to one embodiment of the present disclosure, silica particles, that can be used for forming a prepreg having excellent adhesion to a metal substrate layer when mixed with a liquid composition containing a thermosetting resin and cured, are provided.

According to one embodiment of the present disclosure, a liquid composition and a prepreg capable of forming a cured product having excellent toughness are provided. According to one embodiment of the present disclosure, a metal substrate with a resin and a wiring board, that include the liquid composition capable of forming a cured product having excellent toughness, or a semi-cured product, a prepreg, or a cured product thereof, are provided. According to one embodiment of the present disclosure, silica particles that can be used for forming a prepreg capable of forming a cured product having excellent toughness, by being mixed with a liquid composition containing a thermosetting resin, are provided.

According to one embodiment of the present disclosure, a liquid composition in which wall attachment of silica particles and foaming of the composition during mixing are suppressed and which has excellent dispersibility of silica particles, a prepreg, a metal substrate with a resin, and a wiring board using the liquid composition, and silica particles used in the liquid composition, are provided.

### DESCRIPTION OF EMBODIMENTS

Hereinafter, embodiments of the present disclosure will be described in detail. However, embodiments of the present disclosure are not limited to the following embodiments. Components (including element steps and the like) in the following embodiments are not essential unless otherwise specified. The same applies to numerical values and their ranges, and the numerical values and their ranges do not limit the embodiments of the present disclosure.

In the present disclosure, numerical ranges indicated using “to” includes the numerical values described before and after “to” as the minimum value and the maximum value, respectively.

In the present disclosure, each component may contain plural kinds of corresponding substances. In a case in which plural kinds of substances corresponding to a component are present in the composition, the content or amount of the component means the total content or amount of the plural kinds of substances present in the composition unless otherwise specified.

In the present disclosure, plural kinds of particles corresponding to a component may be contained. When plural kinds of particles corresponding to a component are present in a composition, the particle diameter of the component means a value for the mixture of the plural kinds of particles present in the composition unless otherwise specified.

In the present disclosure, “silica particles” refers to a group of silica particles unless otherwise specified.

In the present disclosure, the “water vapor adsorption amount at a relative water vapor pressure of 0.8 on a water vapor adsorption isotherm at 25° C.” is measured under the following conditions. In the present disclosure, the relative water vapor pressure means the ratio of the pressure of water vapor at adsorption equilibrium to the saturated vapor pressure of water vapor (pressure of water vapor at adsorption equilibrium/saturated vapor pressure of water vapor).

### (Measurement Conditions)

Equipment: BELSORP MINI (manufactured by BEL JAPAN, Inc.)
Measurement principle: Constant volume method
Adsorption temperature: 298K (24.85° C.)
Adsorption gas: Water vapor
Pretreatment: Drying for 1 hour at 150° C. and normal pressure (1.013×10⁵ Pa)
Subject: 1.0 g of silica particles

In the present disclosure, the “moisture retention variation” is calculated by formula (A−B)/A×100, wherein A is a mass-based water content after being left to stand for 24 hours in an environment having a temperature of 85° C. and a relative humidity of 85%, and B is a mass-based water content after being left to stand for 24 hours in an environment having a temperature of 85° C. and a relative humidity of 85% and further being left to stand for 24 hours in an environment having a temperature of 25° C. and a relative humidity of 50%. The moisture content is measured by leaving a sample in the above-described environment using a thermo-hygrostat IG420 model manufactured by Yamato Scientific Co., Ltd. or an equivalent device, and then measuring the moisture content by the Karl Fischer method (coulometric titration method).

### (Conditions for Karl Fischer Method (Coulometric Titration Method))

Trace moisture measuring device (CA-200 manufactured by Mitsubishi Chemical Analytech Co., Ltd.)
Moisture evaporation device (VA-200 manufactured by Mitsubishi Chemical Analytech Co., Ltd.)
Anolyte (HYDRANAL Coulomat AG-OVEN manufactured by Hayashi Pure Chemical Ind., Ltd.)
Catholyte (HYDRANAL Coulomat CG manufactured by Hayashi Pure Chemical Ind., Ltd.)
Heating temperature: 200° C.
Nitrogen flow rate: about 250 mL/min

In the present disclosure, the “charge amount” is measured as follows. First, 10 g of silica particles are placed in an aluminum container (inner dimension: 42 mm; depth: 70 mm) and fixed to a sample rotation arm. The horizontal swing angle is 150 degrees to the left and 210 degrees to the right (swing speed is 540 deg/s), and 12 strokes are counted as one cycle (2 rotations of powder brushing-off are added at the end of 6 strokes in the middle). After three cycles of friction stirring, the charged silica particles are placed in a Faraday cage, and the charge amount of the silica particles is measured and converted into the charge amount per mass (the charge amount of the silica particles/the amount of silica particles supplied: 10 g). The charge amount can be measured using, for example, a powder triboelectric charge amount measuring device (NS-K100 manufactured by Nano Seeds Corporation).

In the present disclosure, the “internal carbon content” is measured as follows. The silica particles are heated in an atmospheric furnace at 500° C. for 1 hour to remove carbon attached to the surface, and then cooled to around 25° C. The obtained silica particles are weighed, and then Sn particles are introduced, and the particles are combusted instantly in a furnace that heated to 1000° C. The amount of carbon dioxide generated is analyzed by mass spectrometry using a mass spectrometer (e.g., PerkinElmer, 2400II, CHN meter). The ratio (% by mass) of carbon contained in the silica particles is defined as the internal carbon content.

In the present disclosure, the “median diameter d50” (hereinafter, also simply referred to as “d50”) is a volume-based cumulative 50% diameter of the particles determined using a laser diffraction particle size distribution measuring device (e.g., “MT3300EXII” manufactured by MicrotracBEL Corp.). In other words, it is a particle diameter at which the cumulative volume on a cumulative curve, obtained by determining the particle size distribution by a laser diffraction/scattering method, is 50%, the entire volume of the particles being set to 100%.

In the present disclosure, the “10% particle diameter d10” (hereinafter, also simply referred to as “d10”) is a volume-based cumulative 10% diameter of the particles determined using a laser diffraction particle size distribution measuring device (e.g., “MT3300EXII” manufactured by MicrotracBEL Corp.). In other words, it is a particle diameter at which the cumulative volume on a cumulative curve, obtained by determining the particle size distribution by a laser diffraction/scattering method, is 10%, the entire volume of the particles being set to 100%.

In the present disclosure, the “specific surface area” is determined by the BET method based on the nitrogen adsorption method using a specific surface area/pore distribution measuring device (e.g., “Tristar II” manufactured by Micromeritics Instrument Corporation).

In the present disclosure, the “powder kinetic friction angle” is an index of powder flowability, and the smaller the value is, the higher the flowability is. The powder kinetic friction angle is measured in accordance with JIS Z 8835 (2016) using a powder bed shear tester (e.g., “NS-S300” manufactured by Nano Seeds Corporation).

In the present disclosure, the “sphericity” refers to an average value obtained by measuring the maximum diameter (DL) and the minor axis (DS) perpendicular to the maximum diameter (DL) of each of 100 random particles in a photographic projection obtained by photographing the particles with a scanning electron microscope (SEM) and calculating the ratio (DS/DL) of the minor axis (DS) to the maximum diameter (DL).

In the present disclosure, the “dielectric tangent” and “dielectric constant” are measured by a perturbation resonator method using a dedicated device (e.g., “Vector Network Analyzer E5063A” manufactured by KEYCOM Corporation).

In the present disclosure, the content of metal elements in silica particles is measured by adding perchloric acid and hydrofluoric acid to the silica particles, igniting the mixture to remove the main component, silicon, and then subjecting the mixture to inductively coupled plasma (ICP) emission spectrometry.

In the present disclosure, the “viscosity” refers to a viscosity at 30 seconds measured at 25° C. for 30 seconds using a rotational rheometer (e.g., Modular Rheometer Physica MCR-301 manufactured by Anton Paar) at a shear rate of 1 rpm.

In the present disclosure, the “thixotropy ratio” is calculated by dividing the viscosity measured at a rotation speed of 1 rpm by the viscosity measured at a rotation speed of 60 rpm using a rotational rheometer.

In the present disclosure, the “weight average molecular weight” is determined using gel permeation chromatography (GPC) in terms of polystyrene.

In the present disclosure, the “surface tension” is measured by the Wilhelmy method using a surface tensiometer for a solvent at 25° C.

In the present disclosure, the “boiling point” is a boiling point at a normal pressure of 1.013×10⁵ Pa.

In the present disclosure, the “evaporation rate” is a relative evaporation rate when the evaporation rate of butyl acetate at 23° C. is set to 1.

In the present disclosure, the “liquid composition” refers to a composition that is liquid at 25° C.

In the present disclosure, the “semi-cured product” refers to a cured product of a liquid composition in a state in which an exothermic peak associated with curing of the thermosetting resin appears when the cured product of the liquid composition is measured by differential scanning calorimetry. In other words, the “semi-cured product” refers to a cured product in which an uncured thermosetting resin remains.

In the present disclosure, the “cured product” refers to a cured product of a liquid composition in a state in which an exothermic peak associated with curing of the thermosetting resin does not appear when the cured product of the liquid composition is measured by differential scanning calorimetry. In other words, the “cured product” refers to a cured product in which an uncured thermosetting resin does not remain.

In the present disclosure, the maximum height roughness Rz is measured in accordance with JIS B 0601 (2013).

A liquid composition 1 according to the present disclosure (hereinafter also referred to as “present composition 1”) contains: a thermosetting resin; and silica particles having: a water vapor adsorption amount at a relative water vapor pressure of 0.8 on a water vapor adsorption isotherm at 25° C. (hereinafter simply referred to as “water vapor adsorption amount) of from 0.01 to 10.00 cm³/g; and a moisture retention variation of 20% or less, the moisture retention variation being calculated by (A−B)/A×100, wherein A is a mass-based water content after being left to stand for 24 hours in an environment having a temperature of 85° C. and a relative humidity of 85%, and B is a mass-based water content after being left to stand for 24 hours in an environment having a temperature of 85° C. and a relative humidity of 85% and further being left to stand for 24 hours in an environment having a temperature of 25° C. and a relative humidity of 50% (hereinafter simply referred to as “moisture retention variation”). In other words, the present composition 1 is a liquid thermosetting composition.

A liquid composition 2 according to the present disclosure (hereinafter also referred to as “present composition 2”) contains a thermosetting resin and silica particles having an absolute charge amount of from 0.7 to 200 nC/g and a d50 of from 1.0 to 10.0 μm. In other words, the present composition 2 is a liquid thermosetting composition.

A liquid composition 3 according to the present disclosure (hereinafter also referred to as “present composition 3”) contains: a thermosetting resin; and silica particles having a powder kinetic friction angle of from 10 to 40 degrees and a median diameter d50 of from 1.0 to 10.0 μm, wherein a ratio of Al to B1 (A1/B1) is from 1.0 to 50.0, wherein Al is a median diameter d50 when the silica particles are dispersed in toluene, and B1 is a median diameter d50 when the silica particles are dispersed in toluene and further subjected to ultrasonic treatment. In other words, the present composition 3 is a liquid thermosetting composition.

The present composition 1 is capable of producing a cured product having excellent adhesion to a metal substrate layer. Although its mechanism of action is unclear, it is briefly estimated as follows. The present composition 1 contains silica particles having specific ranges of water vapor adsorption amount and moisture retention variation. In other words, although the silica particles in the present composition 1 have polar groups such as silanol groups on the surface of the particles, the amount of the polar groups is limited, and the silica particles can be regarded to be those having a low moisture retention capacity, especially at high temperatures. It is believed that, in such silica particles, interaction between polar components contained in the composition and polar sites of the thermosetting resin tends to be well-balanced, whereby the liquid properties, in particular, uniform dispersibility, tend to improve. In addition, it is believed that, in such silica particles, not only is moisture adsorption of the particles themselves suppressed in a high-temperature region at which the thermosetting resin is cured, but also moisture-removal ability is exhibited owing to their hydrophobicity. As a result, in the present composition 1, it is believed that, since a dense network is formed between the silica particles and the thermosetting resin, and since the polar groups on the surfaces of the silica particles improve adhesion to the metal substrate layer, adhesion of a cured product obtained from composition 1 to the metal substrate layer is improved. Further, by the moisture retention variation of the silica particles being within a specific range, it is possible to reduce changes in the moisture content due to environmental changes, and to maintain a uniformly dispersed state. Hereinafter, the adhesion to a metal substrate layer will simply be referred to as “adhesion.”

A cured product obtained from the present composition 2 has excellent toughness. Although the mechanism of action is unclear, it is briefly estimated as follows. The present composition 2 contains silica particles having a d50 and a charge amount within specific ranges. While silica particles having a d50 of about from 1.0 to 10.0 μm can impart a low dielectric tangent, a low dielectric constant, a low linear expansion, and the like to a cured product, there is room for improvement in terms of adhesion to a thermosetting resin. By adjusting the charge amount of the silica particles within a range of from 0.7 to 200 nC/g, the balance of the electrostatic interaction with the thermosetting resin in the present composition 2 can be adjusted, and uniform dispersion of the silica particles and the thermosetting resin can be improved. Therefore, the adhesion of a cured product obtained from the present composition 2 can be improved. As a result, it is believed that toughness of the cured product obtained from the present composition 2 is improved.

According to the present composition 3, wall attachment of the silica particles and foaming of the composition during mixing can be suppressed, whereby a liquid composition having excellent dispersibility of silica particles can be obtained. Although the reason for this is not entirely clear, it is estimated as follows. It is believed that, when mixing a composition containing silica particles, wall attachment due to aggregation of the silica particles or foaming of the composition due to shear occur. The inventors conducted extensive research focusing on the dynamic flowability and aggregation state of the silica particles before mixing, and found that balancing these is effective in preventing the wall attachment of the silica particles and the foaming of the composition. In the present composition 3, the powder kinetic friction angle of the silica particles is from 10 to 40 degrees, and the silica particles have a high degree of dynamic flowability. In the present composition 3, the foregoing ratio (A/B) is from 1.0 to 50.0, and the silica particles are in a state in which aggregation is suppressed, or in a loosely aggregated state. It is believed that balancing the dynamic flowability and the aggregation state suppresses the wall attachment of the silica particles and the foaming of the composition during mixing, and allows the silica particles to be favorably dispersed by mixing.

From the viewpoint of suppressing the aggregation of the silica particles, the viscosities of the present compositions 1, 2, and 3 measured at a rotation speed of 1 rpm are preferably from 130 to 5000 mPa·s, more preferably from 150 to 3000 mPa·s, still more preferably from 180 to 1500 mPa·s, and particularly preferably from 200 to 1000 mPa·s.

From the viewpoint of ease of storage, flowability during use, and the like of the present compositions 1, 2, and 3, the thixotropy ratios of the present compositions 1, 2, and 3, calculated by dividing the viscosity measured at a rotation speed of 1 rpm by the viscosity measured at a rotation speed of 60 rpm, are preferably 3.0 or less, more preferably 2.5 or less, and still more preferably 2.0 or less. The lower limit of the thixotropy ratio is not particularly limited, and may be 0.5 or more.

The present compositions 1, 2, and 3 contain a thermosetting resin. One kind of thermosetting resin may be used, or two or more kinds thereof may be used. Examples of the thermosetting resin include an epoxy resin, a polyphenylene ether resin, a polyimide resin, a phenol resin, and an ortho-divinylbenzene resin. From the viewpoint of adhesion, heat resistance, and the like, the thermosetting resin is preferably an epoxy resin, a polyphenylene ether resin, or an ortho-divinylbenzene resin. The thermosetting resin is preferably a resin containing at least one selected from the group consisting of a phenyl group and a phenylene group.

Examples of the epoxy resin include a bisphenol A-type epoxy resin, a bisphenol F-type epoxy resin, a bisphenol S-type epoxy resin, an alicyclic epoxy resin, a phenol novolac-type epoxy resin, a cresol novolac-type epoxy resin, a bisphenol A novolac-type epoxy resin, a diglycidyl-etherified product of a polyfunctional phenol, and a diglycidyl-etherified product of a polyfunctional alcohol.

The polyphenylene ether resin may be either a modified polyphenylene ether or an unmodified polyphenylene ether. From the viewpoint of adhesion, a modified polyphenylene ether is preferred. The modified polyphenylene ether has a substituent bonded to a polyphenylene ether chain or an end of the polyphenylen ether chain. The substituent is preferably a group having a reactive group, and more preferably a group having a vinyl group, a (meth)acryloyloxy group, or an epoxy group.

A hydrogen atom of a phenylene group in the polyphenylene ether chain may be substituted with an alkyl group, an alkenyl group, an alkynyl group, a formyl group, an alkylcarbonyl group, an alkenylcarbonyl group, or an alkynylcarbonyl group.

From the viewpoint of adhesion, dielectric properties, and the like, the weight average molecular weight of the thermosetting resin is preferably from 1,000 to 7,000, more preferably from 1,000 to 5,000, and still more preferably from 1,000 to 3,000.

From the viewpoint of adhesion of a prepreg or the like obtained from the present composition 1, 2, or 3 to a metal substrate layer of a wiring board or the like, the content of the thermosetting resin with respect to the total mass of the present composition 1, 2, or 3 is preferably from 10% to 40% by mass, more preferably from 15% to 35% by mass, and still more preferably from 20% to 30% by mass.

The present composition 1 contains silica particles having a water vapor adsorption amount of from 0.01 to 10.00 cm³/g and a moisture retention variation of 20% or less.

In addition to the above-described mechanism of action, particularly from the viewpoint of adhesion, the water vapor adsorption amount is preferably from 1.00 to 9.00 cm³/g, and more preferably from 3.00 to 8.50 cm³/g.

In addition to the above-described mechanism of action, particularly from the viewpoint of adhesion, the moisture retention variation is preferably 15% or less, and more preferably 10% or less. The lower limit of the moisture retention variation is not particularly limited, and may be 0%.

In the present composition 2, from the viewpoint of further improving the toughness of the cured product, the charge amount of the silica particles is preferably from 1 to 100 nC/g, more preferably from 1 to 50 nC/g, still more preferably from 1 to 30 nC/g, and particularly preferably from 1 to 10 nC/g.

Further, in the present composition 2, the value obtained by dividing the charge amount (nC/g) of the silica particles by the d50 (μm) of the silica particles is preferably 0.1 or more, more preferably 1 or more, or may be 1.5 or more, or 2 or more. The value obtained by dividing the charge amount of the silica particles by the d50 of the silica particles is preferably 5 or less, more preferably less than 5, and still more preferably 4 or less. When the value obtained by dividing the charge amount of the silica particles by the d50 of the silica particles is within the foregoing ranges, the charge amount of each silica particle tends to be converged to a range in which electrostatic repulsion between the particles and the interaction between the thermosetting resin and the silica particles are balanced, and the above-described mechanism of action tends to be expressed to a higher degree.

In the present composition 1, from the viewpoint of achieving a high level of balance between the physical properties of the composition itself, such as adhesion, dispersion stability, and flowability, and the physical properties of a cured product formed from the composition, such as adhesion and low dielectric tangent, in addition to the above-described mechanism of action, the d50 of the silica particles is preferably from 0.5 to 20.0 μm, more preferably from 1.0 to 10.0 μm, and still more preferably from more than 1.0 μm to 5.0 μm.

In the present composition 2, the d50 of the silica particles is from 1.0 to 10.0 μm. From the viewpoint of achieving a high level of balance between the physical properties of the composition itself, such as dispersion stability and flowability, and the physical properties of a cured product formed from the composition, such as high toughness, adhesion to a metal substrate layer, and low dielectric tangent, the d50 of the silica particles is preferably from more than 1.0 μm to 5.0 μm.

In the present composition 3, the d50 of the silica particles is from 1.0 to 10.0 μm. From the viewpoint of the above-described mechanism of action, in particular, from the viewpoint of more favorably suppressing the wall attachment of the silica particles and the foaming of the composition during mixing, and the viewpoint of suppressing the aggregation of the silica particles, the d50 of the silica particles is preferably from more than 1.0 μm to 5.0 μm, more preferably from 1.5 to 4.0 μm, and still more preferably from 2.0 to 3.5 μm.

In addition to the above-described mechanism of action, from the viewpoint of enhancing the interaction between the silica particles and the thermosetting resin while improving uniform dispersion in the present compositions 1, 2, and 3, the d10 of the silica particles is preferably from 0.5 to 5.0 μm, and more preferably from 1.0 to 3.0 μm.

The ratio of d50 to d10 (d50/d10) is preferably from more than 1.0 to 5.0, more preferably from 1.3 to 4.0, and still more preferably from 1.5 to 3.0, from the viewpoint of improving the uniform dispersion of the silica particles in the present composition while enhancing the interaction between the silica particles and the thermosetting resin.

The particle size distribution of the silica particles contained in the present composition 1, 2, or 3 is preferably unimodal. The fact that the particle size distribution of the silica particles is unimodal can be confirmed by the fact that the particle size distribution measured by the above-described laser diffraction/scattering method has a single peak.

In the present composition 1, from the viewpoint of achieving a higher level of balance between the physical properties of the composition itself, such as adhesion, dispersion stability, and flowability, and the physical properties of a cured product formed from the composition, such as adhesion and low dielectric tangent, in addition to the above-described mechanism of action, the specific surface area of the silica particles is preferably from 0.1 to 10.0 m²/g, more preferably from 0.3 to 3.0 m²/g, and still more preferably from 0.8 to 2.0 m²/g.

In the present composition 2, from the viewpoint of achieving a higher level of balance between the physical properties of the composition itself, such as dispersion stability and flowability, and the physical properties of a cured product formed from the composition, such as high toughness, adhesion to a metal substrate layer, and low dielectric tangent, the specific surface area of the silica particles is preferably from 0.3 to 3.0 m²/g, and more preferably from 0.8 to 2.0 m²/g.

In the present composition 3, from the viewpoint of more favorably suppressing the wall attachment of the silica particles and the foaming of the composition during mixing, and from the viewpoint of suppressing the aggregation of the silica particles, the specific surface area of the silica particles is preferably from 0.1 to 5.0 m²/g, more preferably from 0.2 to 3.5 m²/g, still more preferably from 0.3 to 3.0 m²/g, and particularly preferably from 0.8 to 2.0 m²/g.

From the viewpoint of toughness and adhesion of a cured product of the present composition 1, 2, or 3 to a metal substrate layer, and particularly in the present composition 3, from the viewpoint of more favorably suppressing the wall attachment of the silica particles and the foaming of the composition during mixing, the viewpoint of suppressing the aggregation of the silica particles, or the like, the product A of the specific surface area of the silica particles and the d50 of the silica particles is preferably from 2.7 to 5.0 μm m²/g, and more preferably from 2.9 to 4.5 μm·m²/g. In particular, the product A is preferably 4.0 μmm²/g or less. Silica particles having a product A in this range can be regarded as highly dense spherical particles, and the above-described mechanism of action is more likely to be expressed to a greater extent. In this case, the product A may be 2.7 μm m²/g or more, or may be 2.9 μm m²/g or more.

In the present composition 3, the powder kinetic friction angle of the silica particles is from 10 to 40 degrees. From the viewpoint of more favorably suppressing the wall attachment of the silica particles and the foaming of the composition during mixing, the viewpoint of suppressing the aggregation of the silica particles, and the like, the powder kinetic friction angle of the silica particles is preferably from 20 to 40 degrees.

In the present composition 3, the ratio of A1 to B1 (A1/B1), in which A1 is a d50 when the silica particles are dispersed in toluene, and B1 is a d50 when the silica particles are dispersed in toluene and further subjected to ultrasonic treatment (hereinafter also simply referred to as “ratio (A1/B1)”), is from 1.0 to 50.0. From the viewpoint of more favorably suppressing the wall attachment of the silica particles and the foaming of the composition during mixing, the viewpoint of suppressing the aggregation of the silica particles, and the like, the ratio (A1/B1) is preferably 30.0 or less, more preferably 10.0 or less, still more preferably 5.0 or less, particularly preferably 3.0 or less, and most preferably 2.0 or less. The ratio (A1/B1) is preferably 1.0 or more, and more preferably more than 1.0.

The ratio (A1/B1) is an index of the degree of aggregation of the silica particles before mixing, and is specifically measured as follows. 5% by mass of silica particles in toluene are dispersed using an ultrasonic irradiation apparatus (e.g., “PC-3” manufactured by Beckman Coulter) for an irradiation time of 1 minute. The d50s of the silica particles before and after the ultrasonic dispersion are measured, and the ratio (A1/B1) is calculated.

In the present disclosure, unless otherwise specified regarding the ultrasonic dispersion, the descriptions of the particle size of the silica particles (including the particle size distribution, d50, d10, and d50/d10) are descriptions of the particle size measured by preparing a measurement solution after dispersing the silica particles in water and ultrasonically dispersing the particles under the above-described conditions.

In the present composition 3, the repose angle of the silica particles is preferably from 25 to 50 degrees, or may be from 20 to 40 degrees, from the viewpoint of more favorably suppressing the wall attachment of the silica particles and the foaming of the composition during mixing, and from the viewpoint of suppressing the aggregation of the silica particles. The repose angle is determined by passing a powder sample through a vibrating sieve having a diameter of 80 mm and a mesh size of 710 μm, and then gently allowing the powder sample to fall from a funnel placed at a height of 160 mm onto a horizontal plane of a table having a diameter of 80 mm, and measuring the angle between the horizontal plane and the generating line of a cone formed by the powder. The more favorable the flowability of the powder is, the smaller the value is. Here, the amount of the powder dropped is such that the repose angle becomes substantially stable.

The shape of each silica particle of the silica particles is preferably spherical, from the viewpoint of achieving a high level of balance between the physical properties of the present composition 1, 2 or 3 itself, such as dispersion stability and flowability, and the physical properties of a shaped material formed from the present composition 1, 2 or 3, such as high toughness, adhesion to a metal substrate layer, and low dielectric tangent, in addition to the above-described mechanism of action. From the same viewpoint, the sphericity of the spherical silica particles is preferably 0.75 or more, more preferably 0.90 or more, still more preferably 0.93 or more, and particularly preferably 1.00. Further, from the same viewpoint, the silica particles are preferably non-porous particles.

From the viewpoint of reducing transmission loss in a circuit when using a metal substrate with a resin as a printed wiring board, the dielectric tangent of the silica particles is preferably 0.0020 or less, more preferably 0.0010 or less, and still more preferably 0.0008 or less, at a frequency of 1 GHz.

From the same viewpoint, the dielectric constant of the silica particles is preferably 5.0 or less, more preferably 4.5 or less, and still more preferably 4.1 or less, at a frequency of 1 GHz.

Each silica particle may be treated with a silane coupling agent. By treating the surface of the silica particles with a silane coupling agent, the amount of remaining silanol groups on the surface is reduced, the surface is hydrophobized, and moisture adsorption is suppressed, whereby the dielectric loss is improved. It also enhances the affinity with the thermosetting resin in the present composition, and improves adhesion, dispersion, and strength after resin film formation.

Examples of the silane coupling agent include an aminosilane-based coupling agent, an epoxysilane-based coupling agent, a mercaptosilane-based coupling agent, a silane-based coupling agent, and an organosilazane compound. One type of silane coupling agent may be used singly, or two or more types thereof may be used in combination.

The amount of the silane coupling agent attached is preferably from 0.01 to 5 parts by mass, and more preferably 0.10 to 2 parts by mass, with respect to 100 parts by mass of the silica particles.

The fact that the surface of the silica particles has been treated with a silane coupling agent can be confirmed by detecting a peak of a substituent of the silane coupling agent by IR. The amount of the silane coupling agent attached can be measured based on the amount of carbon.

On the other hand, from the viewpoint of enhancing the interaction between the silica particles and the thermosetting resin thereby improving the toughness of the cured product, it is also preferable that each silica particle is not surface-treated with a silane coupling agent or the like. In particular, in the present composition 2, particles that have not been surface-treated with a silane coupling agent or the like (hereinafter also referred to as “non-surface-treated particles”) are preferable.

In particular, in the present composition 2, from the viewpoint of further improving the toughness of the cured product, the internal carbon content of the silica particles is preferably 10% by mass or less, more preferably 5% by mass or less, still more preferably 3% by mass or less, particularly preferably 1% by mass or less, and most preferably 0% by mass.

From the viewpoint of adhesion of the present composition, the content of metal element(s) in silica particles is preferably from 30 to 1500 ppm by mass, more preferably from 100 to 1000 ppm by mass, and still more preferably from 100 to 500 ppm by mass.

Examples of the metal element include Ti, Na, K, Mg, Ca, Al, and Fe.

The silica particles preferably contain from 30 to 1500 ppm by mass, more preferably from 100 to 1000 ppm by mass, still more preferably from 100 to 500 ppm by mass, of titanium (Ti). Ti is a component that is optionally included in the production of the silica particles. During the production of the silica particles, generation of fine powder due to cracking of the silica particles increases the specific surface area of the particles. By adding Ti during the production of the silica particles, the particles can be easily compacted by heat during firing, and the cracking of the particles can be suppressed. As a result, the generation of fine powder can be suppressed, and the amount of particles attached to the surface of the base particles of the silica particles can be reduced, making it easier to adjust the specific surface area of the silica particles. By including 30 ppm by mass or more of Ti, the silica particles are easily thermally compacted during the firing, and the generation of fine powder due to cracking can be suppressed. When the Ti content is 1,500 ppm by mass or less, in addition to obtaining the foregoing effect, increase in the amount of silanol groups can be suppressed, thereby lowering the dielectric tangent.

The silica particles may contain metal element(s) other than Ti as long as the effects of the present disclosure are not impaired. Examples of the metal element other than Ti include Na, K, Mg, Ca, Al, and Fe. The total content of alkali metals and alkaline earth metals among the metal element(s) is preferably 1500 ppm by mass or less, more preferably 1000 ppm by mass or less, and still more preferably 200 ppm by mass or less. Further, the content of Na among the metal element(s) is preferably 1500 ppm by mass or less, more preferably 1000 ppm by mass or less, and still more preferably 200 ppm by mass or less.

The silica particles are preferably silica particles produced by a wet method. The wet method refers to a technique that involves a process of gelling a liquid silica source to obtain a raw material for the silica particles. By using the wet method, the shape of the silica particles tends to be easily adjusted, and in particular, spherical silica particles tend to be easily prepared. Therefore, it is not necessary to adjust the particle shape by crushing or the like, and as a result, particles with a small specific surface area tend to be easily obtained. Further, in the wet method, particles that are significantly smaller than the average particle diameter are less likely to be generated, and the specific surface area after the firing tends to be small. In addition, in the wet method, the amount of impurity elements, such as titanium, can be adjusted by adjusting the impurities in the silica source, and further, the above-described impurity elements can be uniformly dispersed in the particles.

Examples of the wet method include a spray method and an emulsion-gelation method. In the emulsion-gelation method, for example, a continuous phase and a dispersed phase containing a silica precursor are emulsified, and the resulting emulsion is gelled to obtain a spherical silica precursor. A preferred emulsification method is a method in which a dispersed phase containing a silica precursor is added to a continuous phase through a microporous portion or a porous membrane, thereby preparing an emulsion. This allows the production of an emulsion having a uniform droplet size, resulting in spherical silica particles having a uniform particle diameter. Examples of such an emulsification method include a micromixer method and a membrane emulsification method. For example, the micromixer method is disclosed in WO2013/062105.

The silica particles can be obtained by heat-treating the silica precursor. The heat treatment has an effect of sintering the spherical silica precursor to densify the shell, as well as reducing the amount of silanol groups on the surface to lower the dielectric tangent. The temperature of the heat treatment is preferably 700° C. or more. From the viewpoint of suppressing the aggregation of the particles, the temperature of the heat treatment is preferably 1600° C. or less. Further, the obtained silica particles may be surface-treated with a silane coupling agent. On the other hand, from the viewpoint of the toughness of the cured product, it is also preferable that the surface treatment is not carried out.

From the viewpoint of the toughness of the cured product and the adhesion to a metal substrate layer, the content of the silica particles with respect to 100 parts by mass of the thermosetting resin in the present compositions 1 and 2 is preferably 50 parts by mass or more, more preferably 70 parts by mass or more, still more preferably 90 parts by mass or more, and particularly preferably 100 parts by mass. The content is preferably 400 parts by mass or less, more preferably 300 parts by mass or less, and still more preferably 250 parts by mass or less.

From the viewpoint of more favorably suppressing the wall attachment of the silica particles and the foaming of the composition during mixing, the viewpoint of suppressing the aggregation of the silica particles, and the viewpoint of reducing water absorption, low dielectric tangent, adhesion, and the like, the content of the silica particles with respect to 100 parts by mass of the thermosetting resin in the present composition 3 is preferably from 10 to 400 parts by mass, more preferably from 50 to 300 parts by mass, and still more preferably from 70 to 250 parts by mass. In particular, when a high filling rate of the silica particles is desired, the content of the silica particles is preferably 80 parts by mass or more, more preferably 90 parts by mass or more, and particularly preferably 100 parts by mass or more. In this case, the content of the silica particles may be 400 parts by mass or less, 300 parts by mass or less, or 250 parts by mass or less.

By the above-described mechanism of action, the silica particles in the present composition 1, 2, or 3 are in a state in which the particles are sufficiently wetted and uniformly dispersed, whereby the silica particles easily interact with the thermosetting resin. Therefore, even in the present composition in which the foregoing content is within these ranges, in other words, in the present composition in which the filling rate of the silica particles with respect to the thermosetting resin is high, both components tend to be easily stabilized, and a cured product having excellent adhesion to a metal substrate layer can be formed.

The present composition may contain one or more curing agents. A curing agent is an agent that initiates a curing reaction of a thermosetting resin by the action of heat. Specific examples thereof include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. The amount of the curing agent with respect to 100 parts by mass of the thermosetting resin is preferably from 0.1 to 5 parts by mass.

The present composition may contain one or more curing accelerators. Examples E of the curing accelerator include: a trialkenyl isocyanurate compound, such as triallyl isocyanurate; a polyfunctional acrylic compound having two or more acryloyl or methacryloyl groups in the molecule; a polyfunctional vinyl compound having two or more vinyl groups in the molecule; and a vinylbenzyl compound having a vinylbenzyl group in the molecule, such as styrene. The amount of the curing accelerator with respect to 100 parts by mass of the thermosetting resin is preferably from 10 to 100 parts by mass.

The present composition 1, 2, or 3 may contain one or more kinds of solvents. From the viewpoint of reducing the water absorption rate of the present composition 1, 2, or 3 and a cured product thereof, the surface tension of the solvent is preferably 45 mN/m or less, more preferably 40 mN/m or less, still more preferably 35 mN/m or less, and particularly preferably 30 mN/m or less. The lower limit of the surface tension is not particularly limited, and may be 5 mN/m or more.

From the viewpoint of ease of handling at the time of thermally curing the present composition 1, 2, or 3 to form a shaped material such as a prepreg, the boiling point of the solvent is preferably 75° C. or higher, more preferably 80° C. or higher, and still more preferably 90° C. or higher. The upper limit of the boiling point is not particularly limited, and may be 200° C. or less.

When the evaporation rate of butyl acetate at 23° C. is set to 1, from the viewpoint of ease of handling at the time of thermally curing the present composition 1, 2, or 3 to form a shaped material such as a prepreg, the evaporation rate of the solvent is preferably from 0.3 to 3.0, and more preferably from 0.4 to 2.0.

Examples of the solvent include acetone, methanol, ethanol, butanol, 2-propanol, 2-methoxyethanol, 2-ethoxyethanol, toluene, xylene, methyl ethyl ketone, N,N-dimethylformamide, methyl isobutyl ketone, N-methylpyrrolidone, n-hexane, and cyclohexane. From the viewpoint of adhesion of a cured product to a metal substrate layer or the like, it is preferable that the solvent includes at least one selected from the group consisting of toluene (110° C., 28 mN/cm, 0.58), cyclohexanone (156° C., 35 mN/cm, 0.32), methyl ethyl ketone (80° C., 24.6 mN/cm, 3.7), and N-methylpyrrolidone (202° C., 42 mN/m, from 0.3 to 4.0). The numbers in the parentheses indicate the boiling point, the surface tension, and the evaporation rate in this order.

The content of the solvent with respect to the total mass of the present composition is not particularly limited, and may be from 10% to 60% by mass.

The present composition 1, 2, or 3 may contain one or more kinds of plasticizers. Examples of the plasticizer include a butadiene-styrene copolymer. The content of the plasticizer with respect to 100 parts by mass of a thermosetting resin is preferably from 10 to 50 parts by mass, and more preferably from 20 to 40 parts by mass.

The present composition may further contain, in addition to the above-described components, other component(s) such as a surfactant, a thixotropic agent, a pH adjuster, a pH buffer, a viscosity regulator, a defoamer, a silane coupling agent, a dehydrating agent, a weathering agent, an antioxidant, a heat stabilizer, a lubricant, an antistatic agent, a brightener, a colorant, a conductive material, a release agent, a surface treatment agent, a flame retardant, or various organic or inorganic fillers, as long as the effects of the composition are not impaired.

A prepreg 1 according to the present disclosure includes: the present composition 1 or a semi-cured product thereof; and a fibrous substrate.

A prepreg 2 according to the present disclosure includes: the present composition 2 or a semi-cured product thereof; and a fibrous substrate.

A prepreg 3 according to the present disclosure includes: the present composition 3 or a semi-cured product thereof; and a fibrous substrate.

The fibrous substrate preferably contains a glass component. Examples of the fibrous substrate include glass cloth, aramid cloth, polyester cloth, glass nonwoven fabric, aramid nonwoven fabric, polyester nonwoven fabric, and pulp paper. The thickness of the fibrous substrate is not particularly limited, and may be from 3 to 10 μm. Since the present compositions 1 to 3 are described above, the description thereof will be omitted here.

The prepreg 1, 2, or 3 according to the present disclosure can be produced by coating or impregnating the fibrous substrate with the corresponding present composition 1, 2, or 3. After the coating or impregnation with the present composition 1, 2, or 3, the liquid composition may be heated to be semi-cured.

The metal substrate with a resin 1 according to the present disclosure includes: the present composition 1 or a semi-cured product thereof or the above-described prepreg 1; and a metal substrate layer. The metal substrate layer may be provided at one side or both sides of the present composition 1 or the semi-cured product or the above-described prepreg 1.

The metal substrate with a resin 2 according to the present disclosure includes: the present composition 2 or a semi-cured product thereof or the above-described prepreg 2; and a metal substrate. The metal substrate layer may be provided at one side or both sides of the present composition 2 or the semi-cured product or the above-described prepreg 2.

The metal substrate with a resin 3 according to the present disclosure includes: the present composition 3 or a semi-cured product thereof or the above-described prepreg 3; and a metal substrate. The metal substrate layer may be provided at one side or both sides of the present composition 3 or the semi-cured product or the above-described prepreg 3.

The type of the metal substrate layer is not particularly limited, and examples of the metal constituting the metal substrate layer include copper, a copper alloy, stainless steel, nickel, a nickel alloy (including alloy 42), aluminum, an aluminum alloy, titanium, and a titanium alloy. The metal substrate layer is preferably a metal foil, and more preferably a copper foil, such as a rolled copper foil or an electrolytic copper foil. The surface of the metal foil may be subjected to an anti-rust treatment (such as an oxide film of chromate or the like) or a roughening treatment. As the metal foil, a metal foil with a carrier, that has a carrier copper foil (thickness: from 10 to 35 μm) and an ultra-thin copper foil (thickness: from 2 to 5 μm) layered on the surface of the carrier copper foil via a release layer, may be used. The surface of the metal substrate layer may be treated with a silane coupling agent. In this case, the entire surface of the metal substrate layer may be treated with the silane coupling agent, or only a part of the surface of the metal substrate layer may be treated with the silane coupling agent. Those mentioned above may be used as the silane coupling agent.

The thickness of the metal substrate layer is preferably from 1 to 40 μm, and more preferably from 2 to 15 μm. From the viewpoint of reducing transmission loss when the metal substrate with a resin is used as a printed wiring board, the maximum height roughness (Rz) of the metal substrate layer (e.g., copper foil) is preferably 2 μm or less, and more preferably 1.2 μm or less. It is preferable that the Rz of the surface of the metal substrate layer (e.g., copper foil) facing the liquid composition, the semi-cured product, or the prepreg is within the foregoing ranges. When a metal substrate with a resin is used as a printed wiring board, transmission loss can generally be reduced, whereas, in general, adhesion between the metal substrate layer and the prepreg or the like tends to decrease. According to the prepreg 1, 2, or 3 using the present composition 1, 2, or 3 according to the present disclosure, the foregoing decrease in adhesion can be suppressed, and the transmission loss can be reduced.

In one embodiment, the metal substrate with a resin 1, 2, or 3 according to the present disclosure can be produced by coating the surface of the metal substrate layer with the corresponding present composition 1, 2, or 3. After the coating of the present composition 1, 2, or 3, the liquid composition may be heated to be semi-cured.

In another embodiment, the metal substrate with a resin 1, 2, or 3 according to the present disclosure can be produced by layering the metal substrate layer and the corresponding prepreg 1, 2, or 3. Examples of the method of layering the metal substrate layer and the prepreg 1, 2, or 3 include a method of subjecting them to thermal compression bonding.

A wiring board 1 according to the present disclosure includes a cured product of the present composition 1 and a metal wiring.

A wiring board 2 according to the present disclosure includes a cured product of the present composition 2 and a metal wiring.

A wiring board 3 according to the present disclosure includes a cured product of the present composition 3 and a metal wiring.

As the metal wiring, a metal wiring produced by, for example, etching the above-described metal substrate layer can be used.

The wiring board 1, 2, or 3 according to the present disclosure can be produced, for example, by a method of etching the metal substrate layer of the above-described corresponding metal substrate with a resin 1, 2, or 3, or a method of forming a pattern circuit on the surface of a cured product of the present composition 1, 2, or 3 by electrolytic plating (semi-additive process (SAP process), modified semi-additive process (MSAP process), or the like).

In one embodiment, silica particles are used for forming a prepreg by being mixed with a liquid composition containing a thermosetting resin, wherein the silica particles have a water vapor adsorption amount of from 0.01 to 10.00 cm³/g and a moisture retention variation of 20% or less.

In another embodiment, silica particles are used for forming a prepreg by being mixed with a liquid composition containing a thermosetting resin, wherein the silica particles have an absolute charge amount of from 0.7 to 200 nC/g, and a d50 of from 1.0 to 10.0 μm.

In another embodiment, silica particles are used for forming a prepreg by being mixed with a liquid composition containing a thermosetting resin, wherein the silica particles have a powder kinetic friction angle of from 10 to 40 degrees and a d50 of from 1.0 to 10.0 μm, and wherein the ratio of A1 to B1 (A1/B1) is from 1.0 to 50.0, wherein A1 is a median diameter d50 when the silica particles are dispersed in toluene, and B1 is a median diameter d50 when the silica particles are dispersed in toluene and further subjected to ultrasonic treatment.

Preferred embodiments and numerical ranges of the charge amount, the particle size distribution, d50, d10, the specific surface area, d50/d10, the product of the specific surface area and the d50 of the silica particles, the powder kinetic friction angle, the ratio (A1/B1), the repose angle, the shape, the sphericity, the dielectric tangent, the water vapor adsorption amount, the water retention variation, the internal carbon content, the surface treatment, the elements that can be contained, the production method, and the like, of the silica particles are described above, and therefore, are omitted here. As described above, the silica particles may contain metal element(s).

### EXAMPLES

Hereinafter, embodiments of the present disclosure will be described in detail with reference to Examples. However, the embodiments of the present disclosure are not limited thereto.

### 1. Preparation of Components for Producing Liquid Composition

### [Thermosetting Resin]

Polyphenylene ether resin: Modified polyphenylene ether in which the terminal hydroxyl groups of polyphenylene ether are modified with methacryloyloxy groups (Noryl SA9000 manufactured by SABIC; Mw: 1700; number of functional groups per molecule: 2)

### [Silica Particles]

Silica particles A: Silica particles obtained by filling an alumina crucible with 15 g of silica powder 1 (H-31 manufactured by AGC Si-Tech Co., Ltd.; d50:3.5 μm; specific surface area: 1.0 m²/g) produced by a wet method, heat-treating the powder at a temperature of 1200° C. in an electric furnace for 1 hour, followed by cooling to 25° C. and then crushing in an agate mortar (water vapor adsorption amount: 6.00 cm³/g; moisture retention variation: 5%; Na content: 20 ppm by mass; total amount of metal elements: 40 ppm; charge amount: 8 nC/g; internal carbon content: 0% by mass)

Silica particles B: Silica particles obtained by filling an alumina crucible with 15 g of silica powder (E-2C manufactured by SUZUKIYUSHI INDUSTRIAL CORPORATION; d50:2. 5 μm; specific surface area: 2.2 m²/g) produced by a wet method, heat-treating the powder at a temperature of 1200° C. in an electric furnace for 1 hour, followed by cooling to 25° C. and then crushing in an agate mortar (water vapor adsorption amount: 8.00 cm³/g; moisture retention variation: 8%; Na content: 20 ppm by mass; total amount of metal elements: 40 ppm; charge amount: 10 nC/g; internal carbon content: 0% by mass)

Silica particles C: Silica particles produced by the vaporized metal combustion (VMC) method (SC5500-SQ manufactured by ADMATECHS COMPANY LIMITED; d50: 1.5 μm; specific surface area: 5.0 m²/g; water vapor adsorption amount: 22.00 cm³/g; moisture retention variation: 25%; Na content: 100 ppm by mass; total amount of metal elements: 500 ppm)

Silica particles D: Silica particles produced by a dry method (SPH516 manufactured by NIPPON STEEL Chemical & Material Co., Ltd.; d50: 0.64 μm; specific surface area: 12.7 m²/g; water vapor adsorption amount: 30.00 cm³/g; moisture retention variation: 40%; Na content: 150 ppm by mass; total amount of metal elements: 1700 ppm)

Silica particles C2: model number “H-31” manufactured by AGC Si-Tech Co., Ltd.; charge amount: 12 nC/g; internal carbon content: 0% by mass

Silica particles D2: model number “SO-C2” manufactured by ADMATECHS COMPANY LIMITED; charge amount: 0.03 nC/g; internal carbon content: 0% by mass

Silica particles E2: model number “SEAHOSTAR (registered trademark) KE-S-S150” manufactured by NIPPON SHOKUBAI CO., LTD.; charge amount: 250 nC/g; internal carbon content: 0.8% by mass

Silica particles C3: trade name “HS-206” manufactured by NIPPON STEEL Chemical & Material Co., Ltd.

### [Plasticizer]

Butadiene-styrene random copolymer (Ricon 100, Cray Valley)

### [Curing Accelerator]

Triallyl isocyanurate (TAIC, Mitsubishi Chemical Group Corporation)

### [Curing Agent]

α,α′-Di (t-butylperoxy) diisopropylbenzene (PERBUTYL (registered trademark) P, NOF CORPORATION)

### [Solvent]

### Toluene

2. Production of Liquid Composition, Prepreg, and Metal Substrate with Resin

### Example 11

59 parts by mass of a polyphenylene ether resin, 16 parts by mass of a butadiene-styrene random copolymer, 25 parts by mass of triallyl isocyanurate, 1 part by mass of a, a′-di (t-butylperoxy) diisopropylbenzene, 55 parts by mass of silica particles A, and 80 parts by mass of toluene were placed in a polyethylene bottle. Alumina balls having a diameter (Φ) of 20 mm were added thereto and mixed at 30 rpm for 12 hours, and the alumina balls were then removed to obtain a liquid composition.

The liquid composition was applied to a glass cloth of IPC spec 2116 by impregnation and then heated and dried at 160° C. for 4 minutes to obtain a prepreg.

Copper foils with a carrier (thickness: 3 μm; maximum height roughness Rz: 2 μm; MT18E manufactured by MITSUI MINING & SMELTING CO., LTD.) were layered on both sides of the prepreg, and the laminate was heat-treated at 230° C. and a pressure of 30 kg/cm² for 120 minutes to obtain a metal substrate with a resin.

### Examples 12 to 14

Liquid compositions, prepregs, and metal substrates with a resin were produced in the same manner as in Example 11, except that the silica particles A were replaced with the silica particles shown in Table 1.

### Examples 15 and 16

A liquid composition of Example 15 containing 138 parts by mass of silica particles A with respect to 100 parts by mass of the polyphenylene ether resin was obtained in the same manner as in Example 11 except that the amount of the polyphenylene ether resin was 40 parts by mass. A liquid composition of Example 16 containing 138 parts by mass of silica particles B with respect to 100 parts by mass of the polyphenylene ether resin was obtained in the same manner as in Example 12 except that the amount of the polyphenylene ether resin was 40 parts by mass.

### [Measurement of Peel Strength]

Using the metal substrates with a resin produced in Examples 11 to 16, the HAST test was carried out in accordance with IEC 60068-2-66 (JIS C60068-2-66 (2001)) under the conditions of a temperature of 120° C., a relative humidity of 85%, and an exposure time of 96 hours.

After the HAST test, the peel strength between the cured product and the copper foil with a carrier was measured in accordance with IPC-TM650-2.4.8. The results of the measurement are summarized in Table 1.

Here, Examples 11, 12, 15, and 16 are working examples, and Examples 13 and 14 are comparative examples.

TABLE 1

| | Silica particles | | | | | | | |
|---|---|---|---|---|---|---|---|---|
| | | | | | | | Total | |
| | | | | Water | | Na | amount | |
| | | | Specific | vapor | Moisture | content | of metal | |
| | | | surface | adsorption | retention | (ppm | elements | Peel |
| | | d50 | area | amount | variation | by | (ppm by | strength |
| | Type | (μm) | (m²/g) | (cm³/g) | (%) | mass) | mass) | (lb/in) |
| Example 11 | A | 3.0 | 1.0 | 6.00 | 5 | 20 | 40 | 3.1 |
| Example 12 | B | 2.0 | 2.2 | 8.00 | 8 | 20 | 40 | 2.7 |
| Example 13 | C | 1.5 | 5.0 | 22.00 | 25 | 100 | 500 | 1.4 |
| Example 14 | D | 0.64 | 12.7 | 30.00 | 40 | 150 | 1700 | 0.8 |
| Example 15 | A | 3.0 | 1.0 | 6.00 | 5 | 20 | 40 | 3.0 |
| Example 16 | B | 2.0 | 2.2 | 6.00 | 8 | 20 | 40 | 2.2 |

Table 1 shows that the cured product of prepreg 1 using the present composition 1 has excellent adhesion to the metal substrate layer.

### Example 21

A liquid composition, a prepreg, and a metal substrate with a resin were produced in the same manner as in Example 11.

### Examples 22 to 25

Liquid compositions, prepregs, and metal substrates with a resin were produced in the same manner as in Example 21, except that the silica particles A were replaced with the silica particles shown in Table 2.

### Examples 26 and 27

A liquid composition of Example 26 containing 138 parts by mass of silica particles A with respect to 100 parts by mass of the polyphenylene ether resin was obtained in the same manner as in Example 21, except that the amount of the polyphenylene ether resin was 40 parts by mass. A liquid composition of Example 27 containing 138 parts by mass of silica particles B with respect to 100 parts by mass of the polyphenylene ether resin was obtained in the same manner as in Example 22, except that the amount of the polyphenylene ether resin was 40 parts by mass.

### [Evaluation of Toughness]

The flexural moduli of the metal substrates with a resin produced in Examples 21 to 27 were measured using TENSILON (RTF-1350 manufactured by A&D Company, Limited) in accordance with JIS K7171, with a load cell rating of 10 kN, a span length of 64 mm, and a speed of 2 mm/min. The results of the measurement are summarized in Table 2.

Here, Examples 21, 22, 26, and 27 are working examples, and Examples 23 to 25 are comparative examples.

TABLE 2

| | Silica particles | | | | | |
|---|---|---|---|---|---|---|
| | | | | | Internal | Toughness |
| | | | | | carbon | evaluation |
| | | | Charge | Charge | content | (Flexural |
| | | d50 | amount | amount/d50 | (% by | modulus |
| | Type | (μm) | (nC/g) | (nC/g · μm) | mass) | (GPa)) |
| Example 21 | A | 3.0 | 8 | 2.7 | 0 | 20 |
| Example 22 | B | 2.0 | 10 | 5.0 | 0 | 20 |
| Example 23 | C2 | 3.5 | 0.03 | 0.009 | 0 | 2 |
| Example 24 | D2 | 0.6 | 12 | 20.0 | 0 | 5 |
| Example 25 | E2 | 1.5 | 250 | 166.7 | 0.8 | 3 |
| Example 26 | A | 3.0 | 8 | 2.7 | 0 | 19 |
| Example 27 | B | 2.0 | 10 | 5.0 | 0 | 14 |

Table 2 shows that the metal substrates with a resin using the present composition 2 have higher flexural moduli and are superior in toughness compared to the metal substrates with a resin not using the present composition 2.

### Example 31

A liquid composition was obtained in the same manner as in Example 11, except that kneading was carried out using a planetary dispenser.

The liquid composition was applied to a glass cloth of IPC spec 2116 by impregnation and then heated and dried at 160° C. for 4 minutes to obtain a prepreg.

Three sheets of the prepreg were stacked, and ultra-thin copper foils with a carrier (thickness: 3 μm; Rz: 2 μm; MT18E manufactured by MITSUI MINING & SMELTING CO., LTD.) were layered on top and bottom, and the laminate was heat-treated at 230° C. and a pressure of 30 kg/cm² for 120 minutes to obtain a metal substrate with a resin.

### Examples 32 to 35

Liquid compositions, prepregs, and metal substrates with a resin were produced in the same manner as in Example 31, except that the silica particles A were replaced with the silica particles shown in Table 3.

In each example, the d50, the ratio (A1/B1), the powder kinetic friction angle, and the repose angle of the silica particles were measured by the above-described methods using the above-described instruments.

### [Evaluation of Dispersibility of Liquid Composition]

The median particle size gauge of the liquid composition was determined in accordance with the particle gauge method described in JIS K 5600 Feb. 5 (1999).

### [Evaluation of Wall Attachment During Mixing]

After mixing the components, the adhesion of the silica particles to the wall surface of the planetary dispenser was visually checked, and the adhesion of the silica particles to the wall surface was evaluated according to the following criteria.
A: The thickness of the wall attachment is 0.1 mm or less
B: The thickness of the wall attachment is from more than 0.1 mm to 1.0 mm
C: The thickness of the wall attachment is more than 1.0 mm

### [Evaluation of Foaming During Mixing]

After mixing the components, the foaming of the composition was visually observed and evaluated according to the following criteria.
A: Foaming was observed
C: No foaming was observed

### [Evaluation of Prepreg Uniformity]

The prepregs were observed using an optical microscope at 100× magnification, and the uniformity of the prepreg was evaluated in accordance with to the following criteria.
A: No uneven portion having a diameter (Φ) of 0.5 mm or more was observed.
C: An uneven portion having a diameter (Φ) of 0.5 mm or more was observed.

The results of the evaluation are shown in Table 3. Here, Examples 31 and 32 are working examples, and Examples 33 to 35 are comparative examples.

TABLE 3

| | Silica particles | | | | | Evaluation | | | |
|---|---|---|---|---|---|---|---|---|---|
| | | | | Powder | | | Wall | | |
| | | | | kinetic | | | attachment | | |
| | | | | friction | Repose | particle | of | | |
| | | d50 | Ratio | angle | angle | gauge | silica | | Prepreg |
| | Type | (μm) | (A1/B1) | (°) | (°) | (μm) | particles | Foaming | uniformity |
| Example 31 | A | 3.0 | 1.2 | 25 | 41 | 12 | A | A | A |
| Example 32 | B | 2.0 | 1.4 | 37 | 35 | 8 | A | A | A |
| Example 33 | C3 | 12.7 | 2.4 | 15 | 46 | 30 | A | A | C |
| Example 34 | D2 | 0.6 | 102 | 55 | 55 | >100 | C | C | C |
| Example 35 | E2 | 14.5 | 3.5 | 42 | 20 | 70 | B | C | C |

Table 3 shows that, in Examples 31 and 32, in which the present composition 3 was used, the wall attachment of the silica particles and foaming of the composition during mixing were suppressed. In Examples 31 and 32, the dispersibility of the silica particles is excellent, and the uniformity of the prepreg is excellent.

The disclosures of Japanese Patent Application No. 2022-075461, Japanese Patent Application No. 2022-075462, and Japanese Patent Application No. 2022-075146, filed on Apr. 28, 2022, are incorporated herein by reference in their entirety. All publications, patent applications, and technical standards mentioned herein are incorporated herein by reference to the same extent as if each publication, patent application, and technical standard was specifically and individually indicated to be incorporated by reference.

1. A liquid composition, comprising:
a thermosetting resin; and
silica particles having:
a water vapor adsorption amount of from 0.01 to 10.00 cm³/g at a relative water vapor pressure of 0.8 on a water vapor adsorption isotherm at 25° C.; and
a moisture retention variation of 20% or less, the moisture retention variation being calculated by (A−B)/A×100, wherein A is a mass-based water content after being left to stand for 24 hours in an environment having a temperature of 85° C. and a relative humidity of 85%, and B is a mass-based water content after being left to stand for 24 hours in an environment having a temperature of 85° C. and a relative humidity of 85% and further being left to stand for 24 hours in an environment having a temperature of 25° C. and a relative humidity of 50%.

2. The liquid composition according to claim 1, wherein the silica particles have a specific surface area of from 0.1 to 10.0 m²/g.

3. The liquid composition according to claim 1, wherein the silica particles contain from 30 to 1500 ppm by mass of a metal element.

4. The liquid composition according to claim 1, wherein the silica particles have a median diameter d50 of from 1.0 to 10.0 μm.

5. The liquid composition according to claim 1, wherein an amount of the silica particles with respect to 100 parts by mass of the thermosetting resin is from 50 to 400 parts by mass.

6. The liquid composition according to claim 1, wherein the thermosetting resin is at least one selected from the group consisting of an epoxy resin, a polyphenylene ether resin, and an ortho-divinylbenzene resin.

7. The liquid composition according to claim 1, further comprising at least one solvent selected from the group consisting of toluene, cyclohexanone, methyl ethyl ketone, and N-methylpyrrolidone.

8. A prepreg, comprising:
the liquid composition according to claim 1 or a semi-cured product thereof; and
a fibrous substrate.

9. The prepreg according to claim 8, wherein the fibrous substrate comprises a glass component.

10. A metal substrate with a resin, comprising:
the liquid composition according to claim 1 or a semi-cured product thereof, or a prepreg comprising the liquid composition or a semi-cured product thereof and a fibrous substrate; and
a metal substrate layer.

11. The metal substrate with a resin according to claim 10, wherein the metal substrate layer is a copper foil.

12. The metal substrate with a resin according to claim 11, wherein a maximum height roughness Rz of a surface of the copper foil facing the liquid composition, the semi-cured product, or the prepreg, is 2 μm or less.

13. A wiring board, comprising:
a cured product of the liquid composition according to claim 1; and
a metal wiring.

14. Silica particles for use in forming a prepreg by being mixed with a liquid composition containing a thermosetting resin, wherein the silica particles have:
a water vapor adsorption amount of from 0.01 to 10.00 cm³/g at a relative water vapor pressure of 0.8 on a water vapor adsorption isotherm at 25° C.; and
a moisture retention variation of 20% or less, the moisture retention variation being calculated by (A−B)/A×100, wherein A is a mass-based water content after being left to stand for 24 hours in an environment having a temperature of 85° C. and a relative humidity of 85%, and B is a mass-based water content after being left to stand for 24 hours in an environment having a temperature of 85° C. and a relative humidity of 85% and further being left to stand for 24 hours in an environment having a temperature of 25° C. and a relative humidity of 50%.

15. The silica particles according to claim 14, having a specific surface area of from 0.1 to 10.0 m²/g.
